(19) United States
(12) Patent Application Publication
(10) Pub. No.: US 2025/0110174 A1
(43) Pub. Date: Apr. 3, 2025

(54) APPARATUS AND METHODS FOR THERMAL TESTING WITHIN ELECTRONIC COMPONENT ASSEMBLIES

(71) Applicant: QUALCOMM Incorporated, San Diego, CA (US)

(72) Inventors: Palkesh JAIN, Bangalore (IN); Rahul GULATI, San Diego, CA (US); Niraj Shantilal PALIWAL, Nasik (IN); Nikhil Rajendra PATIL, Bengaluru (IN); Vipul Deepak AHUJA, Bengaluru (IN)

(21) Appl. No.: 18/479,598

(22) Filed: Oct. 2, 2023

(51) Int. Cl. G01R 31/28; H01L 23/367

(52) U.S. Cl. CPC G01R 31/2874; G01R 31/287; H01L 23/3675

(57) ABSTRACT

Methods and apparatuses directed to detecting the degradation of electronic components based on thermal testing. In some examples, a device includes heat detection elements, a temperature controller, a memory, and a processor. The temperature controller can receive a signal from each of the heat detection elements and determine a corresponding operating temperature. The processor can receive the operating temperatures from the temperature controller, and can read from the memory a threshold temperature corresponding to each of the heat detection elements. Further, the processor can compare the operating temperatures to their corresponding threshold temperatures and, based on the comparison, generate thermal error data characterizing detected thermal discrepancies. The processor can transmit the thermal error data to cause further operations, such as the disabling of a safety feature, or the display of a warning message, for example.

### BACKGROUND

### Field of the Disclosure

This disclosure relates generally to electronic component assemblies and, more particularly, to thermal testing within electronic component assemblies.

### Description of Related Art

Electronic component assemblies, such as electronic components (e.g., chips) laid out on printed circuit boards, can degrade and even fail due to heat. The heat may be caused by the electronic components themselves during operation. For example, electrical components such as processors may execute workloads that cause the generation of heat. The processors may, in some instances, undergo an attack, such as a cyberattack, that causes the processors to perform additional or unexpected processing, further increasing the amount of heat they generate. In other examples, electrical components may generate more heat than expected when their supply power is unreliable. For instance, as their supply power varies, the electrical components may attempt to compensate in various ways which causes the generation of additional heat. In yet other examples, as electrical components degrade, they may endure a hard error (e.g., a stuck signal or memory bit) that can also cause them to generate additional heat. In certain applications, such as safety critical applications, the degradation and failing of electrical components due to heat can have drastic consequences. As such, there are opportunities to address these and other problems caused by heat generation within electronic component assemblies.

### SUMMARY

According to an aspect, a die package includes a processor communicatively coupled to a plurality of heat detection elements. The processor is configured to determine a corresponding operating temperature for each of the plurality of heat detection elements. The processor is also configured to generate thermal error data based on the operating temperature and a threshold temperature for each of the plurality of heat detection elements. The processor is further configured to transmit an error signal based on the thermal error data.

According to another aspect, a method by a processor includes determining a corresponding operating temperature for each of a plurality of heat detection elements. The method also includes generating thermal error data based on the operating temperature and a threshold temperature for each of the plurality of heat detection elements. The method further includes transmitting an error signal based on the thermal error data.

According to yet another aspect, a non-transitory, machine-readable storage medium comprises instructions that, when executed by at least one processor, cause the at least one processor to perform operations. The operations include determining a corresponding operating temperature for each of a plurality of heat detection elements. The operations also include generating thermal error data based on the operating temperature and a threshold temperature for each of the plurality of heat detection elements. The operations further include transmitting an error signal based on the thermal error data.

According to even another aspect, a device includes a plurality of heat detection elements, thermal logic electrically coupled to the plurality of heat detection elements, and a processor communicatively coupled to the thermal logic. The thermal logic is configured to receive a first signal for each of the plurality of heat detection elements and, based on the first signal for each of the plurality of heat detection elements, determine a corresponding operating temperature for each of the plurality of heat detection elements. The processor is configured to receive the operating temperature for each of the plurality of heat detection elements from the thermal logic. The processor is also configured to generate thermal error data based on the operating temperature and a threshold temperature for each of the plurality of heat detection elements. The processor is further configured to transmit an error signal based on the thermal error data.

### BRIEF DESCRIPTION OF DRAWINGS

FIG. 1 is a block diagram of an electronic component assembly, according to some implementations;

FIGS. 2A and 2B are block diagrams of an integrated circuit, according to some implementations;

FIG. 3 is a block diagram of an electronic component assembly;

FIGS. 4A and 4B illustrate thermal heat generated within electronic component assemblies;

FIG. 5 illustrates a thermal resistance graph based on the age of electronic components;

FIG. 6 is a flowchart of an exemplary process for detecting degraded components within electronic component assemblies, according to some implementations; and

FIG. 7 is a flowchart of another exemplary process for detecting degraded components within electronic component assemblies, according to some implementations.

### DETAILED DESCRIPTION

While the features, methods, devices, and systems described herein may be embodied in various forms, some exemplary and non-limiting embodiments are shown in the drawings, and are described below. Some of the components described in this disclosure are optional, and some implementations may include additional, different, or fewer components from those expressly described in this disclosure.

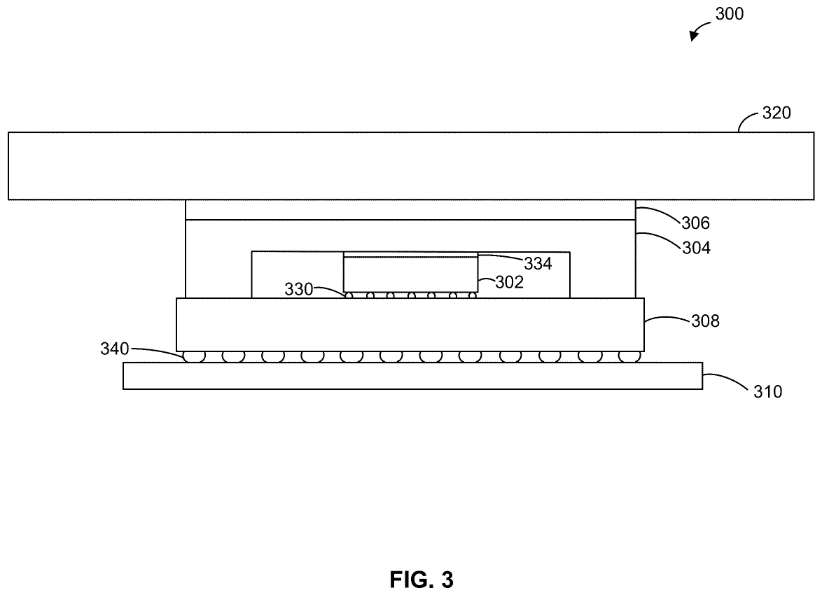

The embodiments described herein are directed to detecting the degradation of electronic components based on thermal testing. For example, FIG. 3 illustrates an electronic component assembly 300 that includes a die 302 that is electrically connected through multiple bumps 330 (e.g., C4 bumps) to a substrate 308. Further, the substrate 308 is electrically connected to a printed circuit board 310 through a ball grid array 340. The electronic component assembly 300 may include a first thermal interface material (TIM) 334 between the die 302 and a lid 304. In addition, the electronic component assembly 300 may also include a second TIM 306 between the lid 304 and a heatsink 320. The first TIM 334 facilities the transfer of heat from the die 302 (e.g., when in operation) to the lid 304, while the second TIM 306 facilitates the transfer of heat from the lid 304 to the heatsink 320. However, first TIM 334 and second TIM 306 can degrade over time, thereby becoming less efficient in the transfer of heat to the heatsink 320. As such, the die 302 may experience more heat that is expected. Further, in some examples, the die 302 may experience a hard fault, which may cause it to generate additional heat as described herein. In other examples, the die 302, which may include a processor, may endure a cyberattack that causes the die 302 to perform additional workloads, thereby generating additional heat. In these and other examples, the performance (e.g., efficiency) of electronic component assembly 300, including die 302, may degrade due to the additional heat that is being endured by the various electronic components

To address these and other thermal issues within electronic component assemblies, the embodiments may include corresponding circuits and processes for detecting the temperatures of electronic components or their surrounding areas to assess and provide an indication of their health (e.g., to assess their thermal aging). For instance, and based on detected temperatures, the embodiments may determine the degradation or failure of electronic components due to various causes such as age, hard failures, or even cyberattacks. The processes described herein may be performed, for example, as a built-in-self-test (BIST) process, such as during bootup of a device, or occasionally during operation of the device.

In some examples, heat detecting elements (i.e., temperature sensors), such as thermistors (e.g., thermal diodes) are placed near (e.g., adjacent to) various thermally important components, such as between layers of a chip, or even near (e.g., adjacent to) electronic components of a printed circuit board (PCB) such as a processor, a power supply, a memory device, a heat sink, or even a fan. The electronic components may then be activated (e.g., a processor may execute a workload), which may spread power over a corresponding chip or printed circuit board, and an operating temperature of electronic components are determined based on the heat detecting elements. The operating temperatures may be compared to corresponding threshold temperatures to determine whether the electronic components have degraded. For instance, the corresponding threshold temperatures may each be a maximum temperature that is expected to be detected, and which was determined and recorded in an ideal condition setting. If an operating temperature is detected above the maximum temperature, a corresponding electronic component may be considered degraded. In some examples, the operating temperatures are compared to a temperature range to determine whether the operating temperature falls within the temperature range. For instance, the embodiments may determine that an electronic component is not operating properly if a corresponding operating temperature is less than a minimum temperature or greater than a maximum temperature. In some instances, to determine a corresponding temperature range, operating temperatures are detected across various scenarios, such as under different workloads and/or different environments. The corresponding temperature range may be used for the comparisons described herein.

In some examples, the embodiments include heat generating elements, such as PCB heaters, positioned near (e.g., adjacent to) electronic components as well as the heat detecting elements. Each heat generating element may be activated to provide a corresponding amount of heat to an electronic component. For example, a heat generation element may be activated for a predetermined amount of time (e.g., several milliseconds, such as three to one hundred milliseconds). The electronic components may be active (e.g., executing workloads) during the predetermined amount of time. Once the predetermined amount of time expires, an operating temperature for the electronic component is determined based on a corresponding heat detecting element. The operating temperatures are then compared to corresponding threshold temperatures to determine whether the electronic components have degraded.

In some examples, an electronic component is activated, and an operating performance value (e.g., an amount of time needed to execute a workload) of the electronic component is determined. The operating performance value may then be compared to a threshold performance value to determine whether the electronic component is operating properly at the corresponding temperature. For instance, one or more heat generating elements may be activated until a particular temperature is measured from a corresponding heat detection element. Once the particular temperature is reached, one or more electronic components, such as a processor and memory device, may be activated to complete one or more workloads. For instance, the processor may write and read data from the memory device until an amount of data is written and/or read. When the one or more workloads complete, an operating amount of time required to complete the one or more workloads is determined. The operating amount of time may then be compared to a threshold amount of time to determine whether the processor and/or memory device are operating correctly.

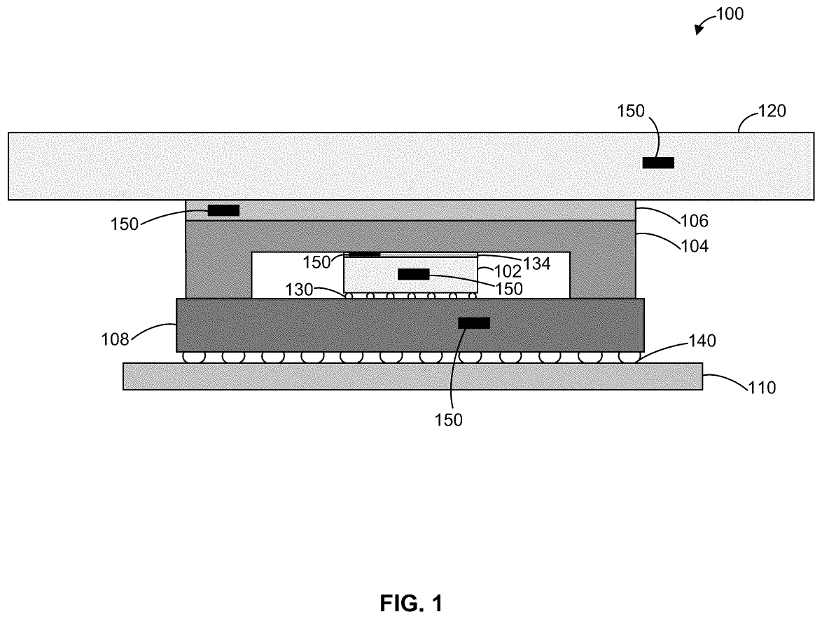

Turning to FIG. 1, an electronic component assembly 100 (e.g., die package) includes a die 102 that is electrically connected through multiple bumps 130 (e.g., C4 bumps, C2 bumps) to a substrate 108. The die 102 may include one or more integrated circuits, such as an integrated circuit that includes one or more processors. For example, the die 102 may be a System-on-a Chip (SoC). Further, the substrate 108 is electrically connected to a printed circuit board 110 through a ball grid array 140. The electronic component assembly 100 may include a first thermal interface material (TIM) 134 between the die 102 and a lid 104. In addition, the electronic component assembly 100 may also include a second TIM 106 between the lid 104 and a heatsink 120. The first TIM 134 facilities the transfer of heat from the die 102 (e.g., when in operation) to the lid 104, while the second TIM 106 facilitates the transfer of heat from the lid 104 to the heatsink 120. In addition, electronic component assembly 100 includes a plurality of heat detection elements 150, such as thermistors. For example, the heat detection elements 150 may alter a resistance based on an amount of detected heat.

In some instances, the die 102 includes a temperature controller that is electrically coupled to the heat detection elements 150. The temperature controller may be configured to receive a signal from each the heat detection elements 150 and, based on the signal, generate thermal data characterizing a temperature of a corresponding heat detection element 150. For instance, the temperature controller may detect changes of a voltage level of the signal provided by the heat detection element 150, and may generate the thermal data based on the detected changes of the voltage level.

The die 102 may also include a processor electrically coupled to the temperature controller. The processor can request and receive from the temperature controller the thermal data for each heat detection element 150, and may determine an operating temperature for each heat detection element 150 based on the corresponding thermal data. For instance, at startup (e.g., bootup), the processor may execute a workload for a predetermined amount of time, causing the die 102 to generate heat. After the predetermined amount of time, the processor may request thermal data from the temperature controller for one or more heat detection elements 150. The thermal data may characterize a temperature sensed for a corresponding heat detection element 150 after the predetermined amount of time. Further, the processor may receive the thermal data, extract a temperature value from the thermal data, and determine the operating temperature for the corresponding heat detection element 150 based on the temperature value.

Additionally, the processor may read from a memory device a threshold temperature corresponding to each of the heat detection elements 150. The memory device may be, for instance, a non-volatile memory (e.g., FLASH, NVRAM) of the die 102, or an external memory electrically coupled to the die 102. The threshold temperatures may characterize a maximum temperature expected to be sensed for each of the heat detection elements 150. The processor may compare, for each of the heat detection elements 150, the operating temperature to the corresponding threshold temperature. Based on the comparison, the processor may generate thermal error data characterizing any thermal discrepancies of the die 102. For example, if the operating temperature is less than the threshold temperature, the processor may determine that there are no thermal discrepancies, and may generate the thermal error data to indicate the same. If, however, the operating temperature is the same as or greater than the threshold temperature, the processor may determine that the die 102 is exhibiting a thermal discrepancy, and may generate the thermal error data to indicate the same.

In some instances, the threshold temperatures characterize a temperature range. In these examples, the processor may determine whether the operating temperature falls within the temperature range (e.g., inclusively). If the operating temperature does not fall within the temperature range, the processor may determine that there are no thermal discrepancies, and may generate the thermal error data to indicate the same. If, however, the operating temperature does fall within the temperature range, the processor may determine that the die 102 is exhibiting a thermal discrepancy, and may generate the thermal error data to indicate the same.

Further, in some examples, when the thermal error data indicates a thermal discrepancy exists, the processor may transmit a thermal error signal to, for example, another electronic component, such as another processor, to take corresponding action. For example, the thermal error signal may cause the electronic component to disable, or limit, one or more functions (e.g., safety functions). In some examples, the thermal error signal may cause the display of a warning message on a display. In yet other examples, the thermal error signal may cause the transmission of a warning message to an electronic device, such as a smartphone. In response to the warning message, a technician may replace the die 102, or may replace a PCB of a system to which the die 102 is electrically connected to.

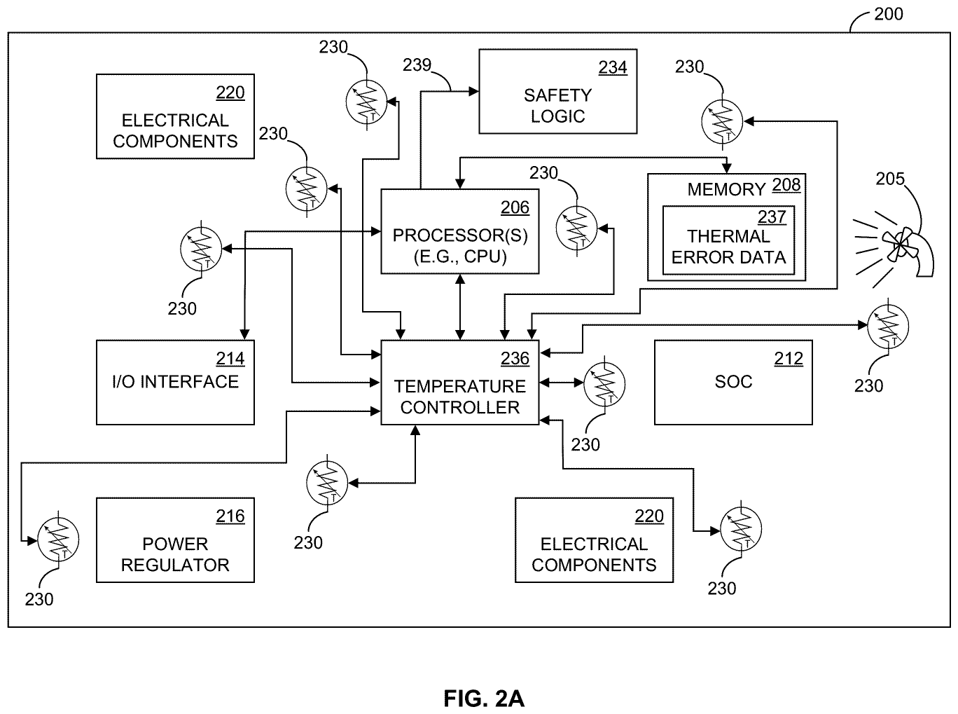

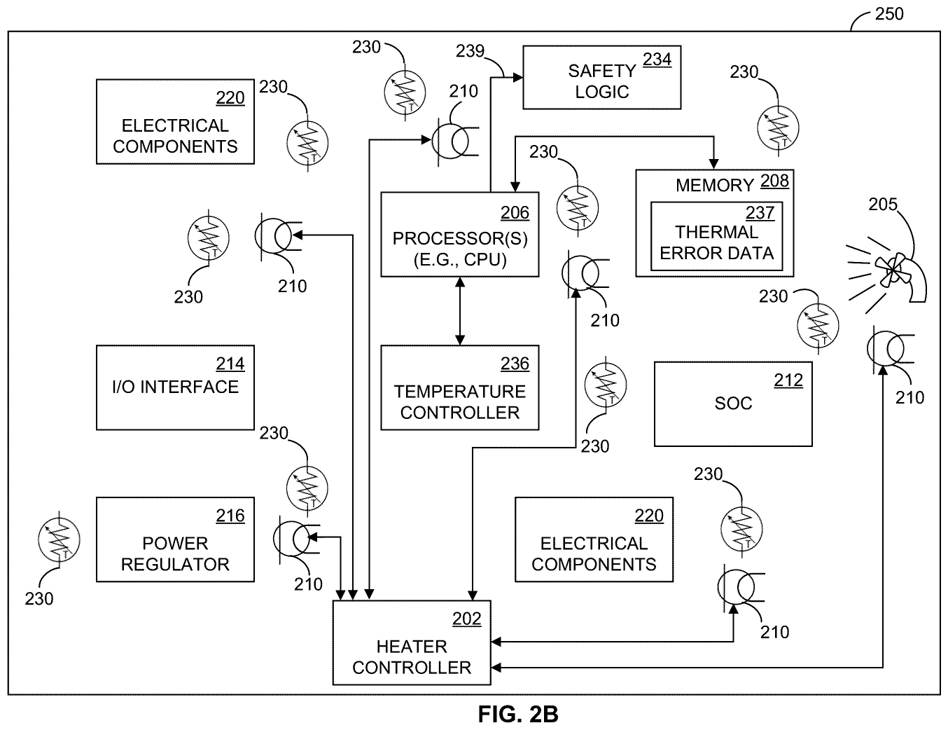

FIG. 2A illustrates an integrated circuit 200 that may be implemented by one or more dies, such as die 102 of FIG. 1. For example, integrated circuit 200 can be a chip, a SoC, a microchip, or a microelectronic circuit, among other examples. As illustrated, integrated circuit 200 includes one or more processors 206, a temperature controller 236, an I/O interface 214, a power regulator 216, a memory 208, safety logic 234, additional electrical components 220, a fan 205, and multiple heat detection elements 230.

Each processor 206 may be, for example, a graphical processing unit (GPU), a central processing unit (CPU), a microcontroller, or any other suitable processing device. The memory 208 may be, for example, a RAM device (e.g., SRAM device), a FLASH device, or any other suitable memory device. Processor 206 is electrically coupled to memory 208 and can read data from, and write data to, memory 208. For instance, processor 206 may be operable to execute instructions stored in memory 208, and/or may be able to store and fetch data needed during operation.

Power regulator 216 may provide power to one or more components of integrated circuit 200. For example, power regulator 216 may receive power over one or more power lines, and may provide regulated power to the components of integrated circuit 200 through one or more voltage rails (e.g., 5 Volt rail, 3.3 Volt rail, etc.). Sensor 212 may be, for example, a camera, an accelerometer, a gyroscope sensor, an optical sensor, or any other suitable sensor. Fan 205 may be any suitable fan, and can blow air across surfaces of the integrated circuit 200. In addition, safety logic 234 may include logic for one or more safety critical features, such as safety critical features in automotive systems, or any other suitable safety logic.

Further, I/O interface 214 may include, for example, any suitable communication interface (e.g., SPI, I2C, FireWire, RS-232, a serial communication interface, a parallel communication interface, a transceiver, etc.). I/O interface 214 is electrically coupled to processor 206, and can allow for communications with external devices such as other integrated circuit boards, and/or with other components of integrated circuit 200, such as sensor 212. Electrical components 220 can include be PCB components, such as resistors, capacitors, diodes, transistors, and other chips.

Additionally, heat detection elements 230 can be any suitable electronic components that can be employed to detect heat. For instance, heat detection elements 230 (i.e., temperature sensors) can be thermistors (e.g., thermal diodes). In some examples, the heat detection elements 230 are positioned near (e.g., adjacent to, on top of, within, below, etc.) components of the integrated circuit 200, such as processor 206, memory 208, power regulator 216, and electrical components 220. Further, temperature controller 236 is electrically coupled to the multiple heat detection elements 230, and can receive a signal from each of the heat detection elements 230 to generate thermal data characterizing a temperature. Temperature controller 236 can be a thermistor controller, and may include one or more processors (e.g., microcontroller, CPU), for instance. In some examples, the temperature controller 236 provides, via an output line (e.g., output pin), an output signal carrying a bias current to a heat detection element 230, and receives, via an input line (e.g., input pin), a input signal. The temperature controller 236 determines a voltage level of the input signal and, based on the voltage level, generates the thermal data characterizing the temperature.

As illustrated, processor 206 is electrically coupled to temperature controller 236, and can receive thermal data for each of the heat detection elements 230 from temperature controller 236. For instance, processor 206 may generate a thermal request message that identifies one or more of the heat detection elements 230 (e.g., by a predetermined identification number). Processor 206 may transmit the thermal request message to the temperature controller 236, causing the temperature controller 236 to generate thermal data, as described herein, for the corresponding heat detection element 230, and to transmit the thermal data to the processor 206. Processor 206 may receive the thermal data, and may determine an operating temperature for the corresponding heat detection element 230 based on the received thermal data. Although illustrated separately, in some examples, processor 206 may perform some or all of the functions described with respect to the temperature controller 236.

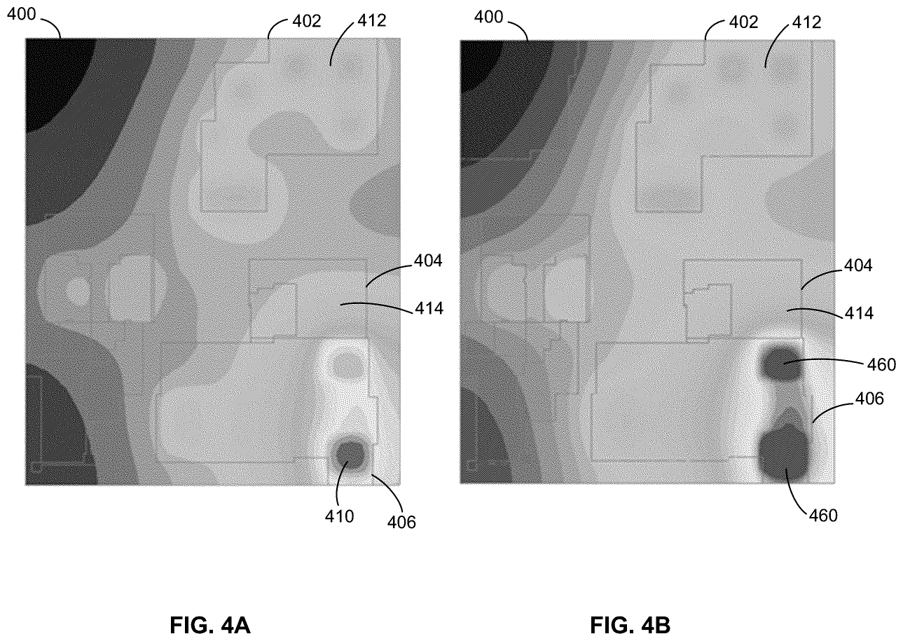

As described herein, the thermal data characterizes a temperature of a corresponding heat detection element 230 based on sensed heat. Components of the integrated circuit 200 that have degraded or failed due to, for example, age, may generate more heat than if they had not degraded or failed. FIGS. 4A and 4B, for example, illustrate temperatures of a printed circuit board 400 over time. For instance, FIG. 4A may illustrate temperatures of the printed circuit board 400 on day one of operation, while FIG. 4B may illustrate temperatures of the printed circuit board years later. As illustrated in FIG. 4A, printed circuit board 400 includes electronic components 402, 404, and 406 that radiate heat during operation. The area 410 around electronic component 406 illustrates a hotter temperature than the area 412 around electronic component 402 or the area 414 around electronic component 404.

In FIG. 4B, while the area 412 around electronic component 402 and the area 414 around electronic component 404 appear to radiate around the same amount of heat as in FIG. 4A, the electronic component 406 in FIG. 4B is now radiating much more heat than in FIG. 4A, as indicated by area 460. This additional heat radiation may be due to the degradation of TIMs meant to transfer heat away from the electronic component 406.

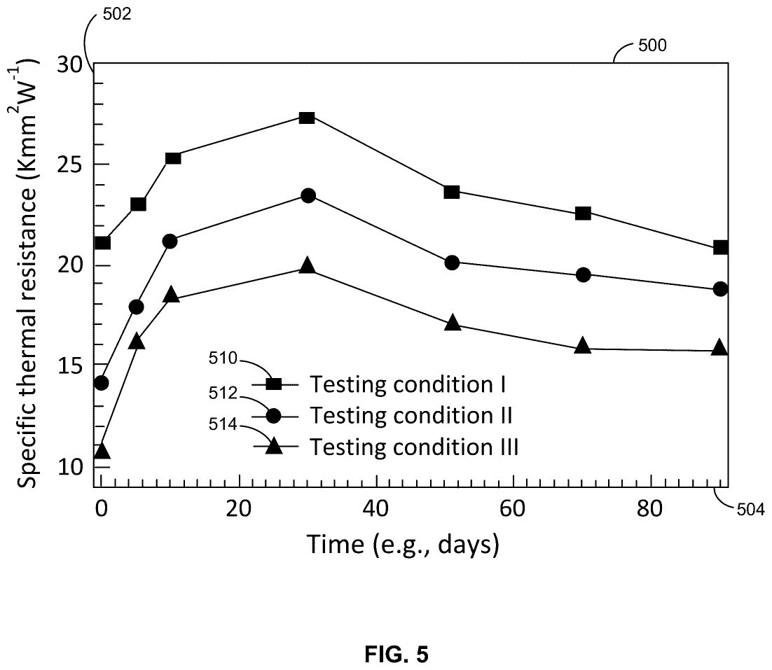

FIG. 5 illustrates a thermal resistance graph 500 that identifies specific thermal resistances 502 along the “Y” axis and component ages 504 of the “X” axis under various testing conditions 510, 512, 514. Specifically, the graph 500 illustrates specific thermal resistance between two copper discs, where the tests are carried out without thermal interface material between the copper discs. Each testing condition 510, 512, 514 may correspond to workload amounts that a component may endure. For instance, and assuming a component of a processor (e.g., processor 206), the first testing condition 510 may correspond to a first workload (e.g., required data processing) that, under the first testing condition 510, the processor endures daily. The second testing condition 512 may correspond to a second workload that, under the second testing condition 512, the processor endures daily. Similarly, the third testing condition 514 may correspond to a third workload that that, under the third testing condition 514, the processor endures daily. In this example, the first workload may be greater than each of the second workload and the third workload. In addition, the second workload is greater than the third workload. As such, under the third testing condition 514, the processor would endure the least amount of workload.

As the thermal resistance graph 500 illustrates, with higher workloads, the specific thermal resistance between the copper discs is generally greater throughout the illustrated ages 504. For each of the testing conditions 510, 512, 514, however, as the component ages, the specific thermal resistance tends to initially increase, but then tends to decrease (e.g., after about 25 days, in this example). As the specific thermal resistance of the components decreases, the components become less efficient in transferring heat away from themselves (e.g., to a heatsink). As a result, the components may tend to degrade or fail sooner than if the specific thermal resistance would not have decreased.

Referring back to FIG. 2A, memory 208 may store threshold temperatures corresponding to each of the heat detection elements 150. As described herein, processor 206 may read from the memory 208 a threshold temperature corresponding to each of the heat detection elements 150, which may characterize a maximum temperature expected to be sensed for each of the heat detection elements 150. Further, processor 206 may compare the operating temperature for a given heat detection element 150 to the corresponding threshold temperature. Based on the comparison, processor 206 may generate thermal error data 237 characterizing any thermal discrepancies of the die 102. For example, if the operating temperature is less than the threshold temperature, processor 206 may determine that there are no thermal discrepancies, and may generate the thermal error data 237 to indicate the same. If, however, the operating temperature is the same as or greater than the threshold temperature, processor 206 may determine that the die 102 is exhibiting a thermal discrepancy, and may generate the thermal error data 237 to indicate the same.

In some instances, the threshold temperatures characterize a temperature range. In these examples, processor 206 may determine whether the operating temperature falls within the temperature range (e.g., inclusively). If the operating temperature does not fall within the temperature range, processor 206 may determine that there are no thermal discrepancies, and may generate the thermal error data 237 to indicate the same. If, however, the operating temperature does fall within the temperature range, processor 206 may determine that the die 102 is exhibiting a thermal discrepancy, and may generate the thermal error data 237 to indicate the same. Processor 206 may store the thermal error data 237 within memory 208.

Further, in some examples, when the thermal error data 237 indicates a thermal discrepancy exists, processor 206 may transmit a thermal error signal 239 (e.g., a warning signal) to, for example, another electronic component, such as safety logic 234, to take corresponding action. For instance, safety logic 234 may disable one or more safety features based on receiving the thermal error signal 239. In some instances, processor 206 transmits the thermal error data 237 to another device using I/O interface 214.

FIG. 2B illustrates an integrated circuit 250 that may be implemented by one or more dies, such as the die 102 of FIG. 1. For example, integrated circuit 250 can be a chip, a SoC, a microchip, or a microelectronic circuit, among other examples. As illustrated, integrated circuit 250 includes one or more processors 206, temperature controller 236, input/output (I/O) interface 214, power regulator 216, memory 208, safety logic 234, additional electrical components 220, fan 205, multiple heat detection elements 230, a heater controller 202, and multiple heat generating elements 210.

In this example, in addition to the multiple heat detection elements 230, the multiple heat generating elements 210 are positioned near components of the integrated circuit 200, such as processor 206, memory 208, power regulator 216, and electrical components 220. Further, heater controller 202 is electrically coupled to the multiple heat generating elements 210, and can transmit a signal to each of the heat generating elements 210 to cause the heat generating elements 210 to generate heat. For instance, heater controller 202 may include one or more processors, and may provide an output signal to one or more heat generating elements 210 to activate them (e.g., to turn the heat generating elements 210 “on”).

Further, as illustrated, processor 206 is electrically coupled to heater controller 202, and can transmit a signal to heater controller 202 to cause heater controller 202 to activate one or more corresponding heat generating elements 210. For instance, processor 206 may generate a heat activation message that identifies one or more of the heat generating elements 210 (e.g., by a predetermined identification number). Processor 206 may transmit the heat activation message to the heater controller 202, causing the heater controller 202 to activate the one or more of the heat generating elements 210 as described herein. Similarly, processor 206 may generate a heat deactivation message that identifies one or more of the heat generating elements 210. Processor 206 may transmit the heat deactivation message to the heater controller 202, causing the heater controller 202 to deactivate the one or more of the heat generating elements 210. Although illustrated separately, in some examples, processor 206 may perform some or all of the operations described herein with respect to the heater controller 202.

In some examples, such as at power-up (e.g., bootup), processor 206 may transmit a heat deactivation message to the heater controller 202 to activate one or more heat generating elements 210 to provide heat to portions of integrated circuit 200 for a predetermined amount of time. Processor 206 may further cause components near the activated heat generating elements 210 to be active during the predetermined amount of time (e.g., processor 206 may write and/or read data from one or more components, such as memory 208 and sensor 212, during the predetermined amount of time). Once the predetermined amount of time expires, processor 206 determines an operating temperature for components near the activated heat generating elements 210 based on requesting and receiving thermal data for one or more nearby a heat detection elements 230 as described herein. Processor 206 may then compare the operating temperatures to the corresponding threshold temperatures to determine whether the electronic components have degraded, and may generate thermal error data 237 based on the comparison, as further described herein.

In some examples, when the thermal error data 237 indicates a thermal discrepancy exists, processor 206 may transmit the thermal error signal 239 to, for example, another electronic component, such as safety logic 234, to take corresponding action. In some instances, processor 206 transmits the thermal error data 237 to another device using I/O interface 214.

In some examples, an electronic component is activated, and an operating performance value (e.g., an amount of time needed to execute a workload) of the electronic component is determined. The operating performance value may then be compared to a threshold performance value to determine whether the electronic component is operating properly at the corresponding temperature. For instance, one or more heat generating elements 210 may be activated as described herein until processor 206 measures a particular temperature from a corresponding heat detection element 230. Once the particular temperature is reached, one or more electronic components, such as the processor 206 and memory 208, may complete one or more workloads. For instance, the processor 206 may write and read data from the memory 208 until an amount of data is written and/or read. When the one or more workloads complete, processor 206 determines an operating amount of time required to complete the one or more workloads. Processor 206 may then compare the operating amount of time to a threshold amount of time to determine whether the processor 206 and/or memory 208 are operating correctly.

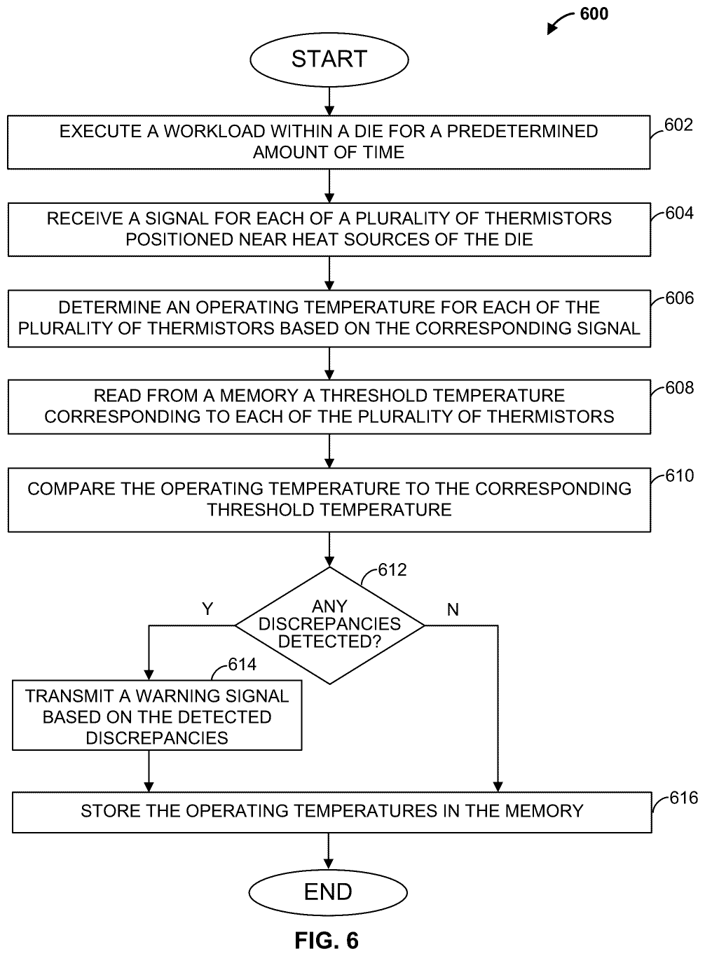

FIG. 6 is a flowchart of an exemplary process 600 for detecting degraded components within electronic component assemblies, such as the electronic component assembly of 100 of FIG. 1. For example, an integrated circuit of an electronic component assembly, such as integrated circuit 200, may perform one or more of the operations of exemplary process 600. In some examples, process 600 may be performed during a BIST process (e.g., during bootup of a device, or occasionally during operation of the device).

Referring to FIG. 6, at block 602, a workload within a die is executed for a predetermined amount of time. For instance, processor 206 may execute a workload for 10 milliseconds. At block 604, a signal is received for each of a plurality of thermistors positioned near heat sources of the die. For example, as described herein, integrated circuit 200 may include multiple heat detection elements 230 positioned near heat generating electronic components, such as processor 206, power regulator 216, I/O interface 214, memory 208, and electrical components 220. In some examples, the processor 206 may receive a signal for each of the heat detection elements 230 from temperature controller 236. As described herein, the signal may identify thermal data for each of the heat detection elements 230. In some examples, processor 206 receives the signals from the heat detection elements 230 and can perform any of the operations of the temperature controller 236 described herein (e.g., processor 206 may include, or be configured to perform similar operations to, the temperature controller 236).

Further, at block 606, an operating temperature is determined for each of the plurality of thermistors based on the corresponding signal. For instance, as described herein, processor 206 may process each signal received to extract or determine thermal data. Based on the thermal data, processor 206 determines an operating temperature for the corresponding heat detection element 230. At block 608, a threshold temperature corresponding to each of the plurality of thermistors is read from a memory. For example, processor 206 may read from memory 208 a single threshold temperature, where the single threshold temperature corresponds to each of the plurality of thermistors. In some examples, processor 206 may read multiple threshold temperatures, where each threshold temperature corresponds to one or more of the plurality of thermistors.

Proceeding to block 610, the operating temperature for each of the plurality of thermistors is compared to the corresponding threshold temperature. For example, as described herein, processor 206 may compare the operating temperature for a given heat detection element 150 to the corresponding threshold temperature. At block 612, a determination is made of whether any thermal discrepancies have been detected based on the comparison. For example, as described herein, if an operating temperature for a thermistor is less than the corresponding threshold temperature, processor 206 determines that there are no thermal discrepancies. If, however, the operating temperature is the same as or greater than the threshold temperature, processor 206 determines that a thermal discrepancy does exist, and may generate the thermal error data 237 to indicate the same.

If no thermal discrepancies are detected, the method proceeds to block 616 where the operating temperatures are stored in memory. For instance, processor 206 may store the operating temperatures for the plurality of thermistors in memory 208. If, however, any thermal discrepancies exist, the method proceeds to block 614.

At block 614, a warning signal is transmitted based on the detected discrepancies. For example, processor 206 may transmit a thermal error signal 239 to, for example, another electronic component, such as safety logic 234, to take corresponding action. For instance, safety logic 234 may disable one or more safety features based on receiving the thermal error signal 239. In some instances, processor 206 transmits the thermal error data 237 to another device using I/O interface 214, such as a device of a technician. The receiving device may display a warning message characterizing the thermal discrepancy to allow the technician to take corresponding action. The method then proceeds to block 616, where the operating temperatures for the plurality of thermistors are stored in the memory.

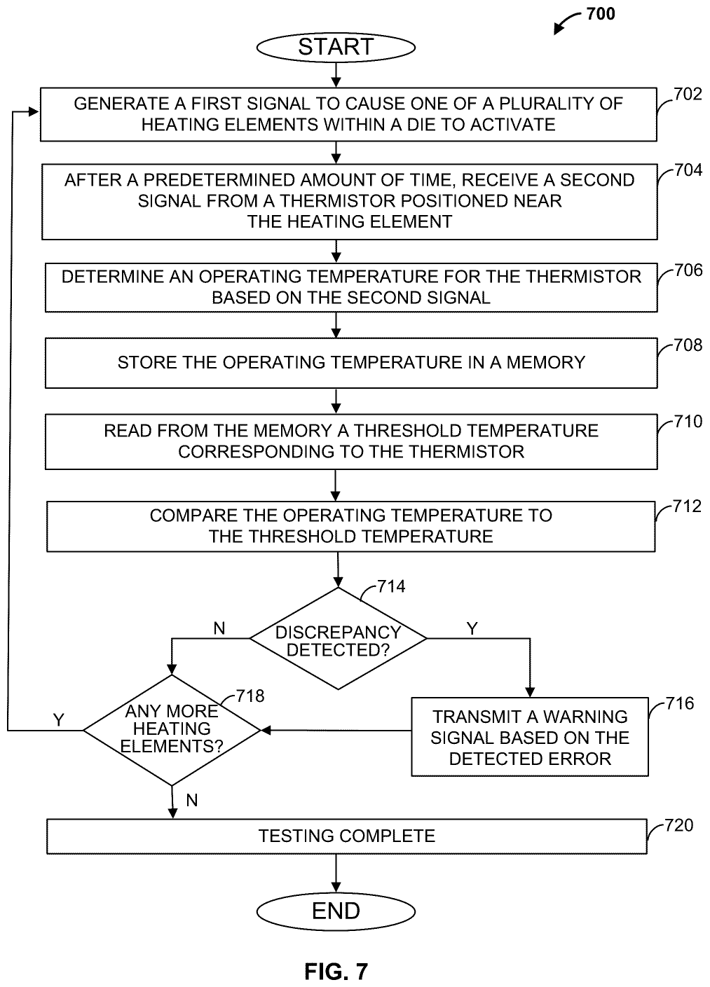

FIG. 7 is a flowchart of an exemplary process 700 for detecting degraded components within electronic component assemblies, such as the electronic component assembly of 100 of FIG. 1. For example, an integrated circuit of an electronic component assembly, such as integrated circuit 250, may perform one or more of the operations of exemplary process 700. In some examples, process 700 may be performed during a BIST process (e.g., during bootup of a device, or occasionally during operation of the device).

Referring to FIG. 7, at block 702, a first signal is generated to cause one of a plurality of heat generating elements within a die to activate. For example, as described herein, processor 206 may transmit a heat deactivation message to heater controller 202, causing heater controller 202 to activate one of the heat generating elements 210. At block 704, after a predetermined amount of time, a second signal is received from a thermistor positioned near the heat generating element. For example, once the predetermined amount of time expires, processor 206 may request and receive, from temperature controller 236, thermal data for a heat detection elements 230 as described herein.

Further, at block 706, an operating temperature for the thermistor is determined based on the second signal. For instance, processor 206 may determine the operating temperature based on the received thermal data. At block 708, the operating temperature is stored in a memory. For example, processor 206 may store the operating temperature in memory 208. Further, at block 710, a threshold temperature is read from the memory. The threshold temperature corresponds to the thermistor. For example, processor 206 may read from memory 208 a threshold temperature, where the threshold temperature corresponds to the thermistor.

Proceeding to block 712, the operating temperature for the thermistor is compared to the corresponding threshold temperature. For example, as described herein, processor 206 may compare the operating temperature for a given heat detection element 150 to the corresponding threshold temperature.

At block 714, a determination is made as to whether a thermal discrepancy has been detected based on the comparison. For example, as described herein, if the operating temperature for the thermistor is less than the corresponding threshold temperature, processor 206 determines that there are no thermal discrepancies. If, however, the operating temperature is the same as or greater than the threshold temperature, processor 206 determines that a thermal discrepancy does exist, and may generate the thermal error data 237 to indicate the same.

If any thermal discrepancies are detected, the method proceeds to block 716 where a warning signal is transmitted based on the detected discrepancies. For example, processor 206 may transmit a thermal error signal 239 to, for example, another electronic component, such as safety logic 234, to take corresponding action. For instance, safety logic 234 may disable one or more safety features based on receiving the thermal error signal 239. In some instances, processor 206 transmits the thermal error data 237 to another device using I/O interface 214, such as a device of a technician. The receiving device may display a warning message characterizing the thermal discrepancy to allow the technician to take corresponding action. The method then proceeds to block 616, where the operating temperatures for the plurality of thermistors are stored in the memory. The method then proceeds to block 718. If, at block 714, no thermal discrepancies are detected, the method also proceeds to block 718.

At block 718, a determination is made as to whether there are any additional heat generating elements to activate (e.g., to test other electronic components and/or portions of a PCB). If there are any additional heat generating elements to activate, the method proceeds back to block 702 to continue the testing. If, however, there are no additional heat generating elements to activate, the method proceeds to block 720, where the testing is complete.

Implementation examples are further described in the following numbered clauses:
1. A die package comprising:
a plurality of heat detection elements; and
a processor communicatively coupled to the plurality of heat detection elements, the processor configured to:
   determine a corresponding operating temperature for each of the plurality of heat detection elements;
   generate thermal error data based on the operating temperature and a threshold temperature for each of the plurality of heat detection elements; and
   transmit an error signal based on the thermal error data.
2. The die package of claim 1, wherein the processor is configured to:
receive a first signal for each of the plurality of heat detection elements; and
based on the first signal for each of the plurality of heat detection elements, determine the corresponding operating temperature for each of the plurality of heat detection elements.
3. The die package of clause 2, wherein the processor is configured to:
execute a workload for a predetermined amount of time; and
receive the first signal for each of the plurality of heat detection elements when the workload has been executed.
4. The die package of any of clauses 1-3 comprising a first thermal interface material, wherein a first of the plurality of heat detection elements contacts the first thermal interface material.
5. The die package of clause 4 comprising a lid, wherein the first thermal interface material is in contact with the lid.
6. The die package of clause 5 comprising a heatsink, wherein a second thermal interface material is between the lid and the heatsink, and wherein a second of the plurality of heat detection elements contacts the second thermal interface material.
7. The die package of any of clauses 1-6 comprising a substrate, wherein a first of the plurality of heat detection elements contacts the substrate.
8. The die package of claim 1 comprising a memory device, wherein the processor is configured to read from the memory device the threshold temperature corresponding to each of the plurality of heat detection elements.
9. The die package of clause 8, wherein a first of the plurality of heat detection elements is positioned adjacent the processor, and a second of the plurality of heat detection elements is positioned adjacent the memory device.
10. The die package of any of clauses 2-9 comprising temperature control logic electrically coupled to the plurality of heat detection elements, wherein the processor is communicatively coupled to the temperature control logic, and wherein the processor is configured to transmit a second signal to the temperature control logic, causing the temperature control logic to transmit the first signal for each of the plurality of heat detection elements to the processor.
11. The die package of any of clauses 1-10 comprising a plurality of heat generating elements, wherein the processor is configured to transmit a signal to each of the plurality of heat generating elements, causing the plurality of heat generating elements to generate heat.
12. The die package of clause 11, wherein the processor is configured to determine the corresponding operating temperature for each of the plurality of heat detection elements a predetermined amount of time after transmitting the signal to each of the plurality of heat generating elements.
13. The die package of any of clauses 1-12 comprising safety logic, wherein the processor is configured to transmit the error signal to the safety logic, causing the safety logic to disable at least one function.
14. A method by a processor comprising:
determining a corresponding operating temperature for each of the plurality of heat detection elements;
generating thermal error data based on the operating temperature and a threshold temperature for each of the plurality of heat detection elements; and
transmitting an error signal based on the thermal error data.
15. The method of claim 14, further comprising:
receiving a first signal for each of the plurality of heat detection elements; and
based on the first signal for each of the plurality of heat detection elements, determining the corresponding operating temperature for each of the plurality of heat detection elements.
16. The method of clause 15, further comprising:
executing a workload for a predetermined amount of time; and
receiving the first signal for each of the plurality of heat detection elements when the workload has been executed.
17. The method of any of clauses 14-16, wherein a first of the plurality of heat detection elements contacts a first thermal interface material.
18. The method of clause 17, wherein the first thermal interface material is in contact with a lid.
19. The method of clause 18, wherein a second thermal interface material is between the lid and the heatsink, and wherein a second of the plurality of heat detection elements contacts a second thermal interface material.
20. The method of any of clauses 14-19, wherein a first of the plurality of heat detection elements contacts a substrate.
21. The method of any of clauses 14-20, comprising reading from a memory device the threshold temperature corresponding to each of the plurality of heat detection elements.
22. The method of any of clauses 14-21, wherein a first of the plurality of heat detection elements is positioned adjacent the processor, and a second of the plurality of heat detection elements is positioned adjacent a memory device.
23. The method of any of clauses 15-22, further comprising transmitting a signal to temperature control logic, causing the temperature control logic to transmit the first signal for each of the plurality of heat detection elements to the processor.
24. The method of any of clauses 14-23, further comprising transmitting a signal to each of a plurality of heat generating elements, causing the plurality of heat generating elements to generate heat.
25. The method of clause 24, further comprising determining the corresponding operating temperature for each of the plurality of heat detection elements a predetermined amount of time after transmitting the signal to each of the plurality of heat generating elements.
26. The method of any of clauses 14-25, further comprising transmitting the error signal to safety logic, causing the safety logic to disable at least one function.
27. A non-transitory, machine-readable storage medium comprises instructions that, when executed by at least one processor, cause the at least one processor to:
determine a corresponding operating temperature for each of a plurality of heat detection elements;
generate thermal error data based on the operating temperature and a threshold temperature for each of the plurality of heat detection elements; and
transmit an error signal based on the thermal error data.
28. The non-transitory, machine-readable storage medium of clause 27, wherein the instructions, when executed by the at least one processor, cause the at least one processor to:
receive a first signal for each of the plurality of heat detection elements; and
based on the first signal for each of the plurality of heat detection elements, determine the corresponding operating temperature for each of the plurality of heat detection elements.
29. The non-transitory, machine-readable storage medium of clause 28, wherein the instructions, when executed by the at least one processor, cause the at least one processor to:
execute a workload for a predetermined amount of time; and
receive the first signal for each of the plurality of heat detection elements when the workload has been executed.
30. The non-transitory, machine-readable storage medium of any of clauses 27-29, wherein a first of the plurality of heat detection elements contacts a first thermal interface material.
31. The non-transitory, machine-readable storage medium of clause 30, wherein the first thermal interface material is in contact with a lid.
32. The non-transitory, machine-readable storage medium of clause 31, wherein a second thermal interface material is between the lid and the heatsink, and wherein a second of the plurality of heat detection elements contacts a second thermal interface material.
33. The non-transitory, machine-readable storage medium of any of clauses 27-32, wherein a first of the plurality of heat detection elements contacts a substrate.
34. The non-transitory, machine-readable storage medium of any of clauses 27-33, wherein the instructions, when executed by the at least one processor, cause the at least one processor to read from a memory device the threshold temperature corresponding to each of the plurality of heat detection elements.
35. The non-transitory, machine-readable storage medium of clause 34, wherein a first of the plurality of heat detection elements is positioned adjacent the at least one processor, and a second of the plurality of heat detection elements is positioned adjacent the memory device.
36. The non-transitory, machine-readable storage medium of any of clauses 28-35, wherein the instructions, when executed by the at least one processor, cause the at least one processor to transmit a second signal to temperature control logic, causing the temperature control logic to transmit the first signal for each of the plurality of heat detection elements to the processor.
37. The non-transitory, machine-readable storage medium of any of clauses 27-36, wherein the instructions, when executed by the at least one processor, cause the at least one processor to transmit a signal to each of a plurality of heat generating elements, causing the plurality of heat generating elements to generate heat.
38. The non-transitory, machine-readable storage medium of clause 37, wherein the instructions, when executed by the at least one processor, cause the at least one processor to determine the corresponding operating temperature for each of the plurality of heat detection elements a predetermined amount of time after transmitting the signal to each of the plurality of heat generating elements.
39. The non-transitory, machine-readable storage medium of any of clauses 27-38, wherein the instructions, when executed by the at least one processor, cause the at least one processor to transmitting the error signal to safety logic, causing the safety logic to disable at least one function.
40. A die package comprising:
a plurality of heat detection elements;
thermal logic electrically coupled to the plurality of heat detection elements, the thermal logic configured to:
   receive a first signal for each of the plurality of heat detection elements; and
   based on the first signal for each of the plurality of heat detection elements, determine a corresponding operating temperature for each of the plurality of heat detection elements; and
a processor communicatively coupled to the thermal logic, the processor configured to:
   receive the operating temperature for each of the plurality of heat detection elements from the thermal logic;
   generate thermal error data based on the operating temperature and a threshold temperature for each of the plurality of heat detection elements; and
   transmit an error signal based on the thermal error data.
41. The die package of clause 40, wherein the thermal logic is configured to:
receive a first signal for each of the plurality of heat detection elements; and
based on the first signal for each of the plurality of heat detection elements, determine the corresponding operating temperature for each of the plurality of heat detection elements.
42. The die package of clause 41, wherein the processor is configured to:
execute a workload for a predetermined amount of time; and
receive the operating temperature for each of the plurality of heat detection elements from the thermal logic when the workload has been executed.
43. The die package of any of clauses 40-42 comprising a first thermal interface material, wherein a first of the plurality of heat detection elements contacts the first thermal interface material.
44. The die package of clause 43 comprising a lid, wherein the first thermal interface material is in contact with the lid.
45. The die package of clause 44 comprising a heatsink, wherein a second thermal interface material is between the lid and the heatsink, and wherein a second of the plurality of heat detection elements contacts the second thermal interface material.
46. The die package of any of clauses 40-45 comprising a substrate, wherein a first of the plurality of heat detection elements contacts the substrate.
47. The die package of any of clauses 40-46 comprising a memory device, wherein the processor is configured to read from the memory device the threshold temperature corresponding to each of the plurality of heat detection elements.
48. The die package of any of clauses 47, wherein a first of the plurality of heat detection elements is positioned adjacent the processor, and a second of the plurality of heat detection elements is positioned adjacent the memory device.
49. The die package of any of clauses 41-48 comprising temperature control logic electrically coupled to the plurality of heat detection elements, wherein the processor is communicatively coupled to the temperature control logic, and wherein the processor is configured to transmit a second signal to the temperature control logic, causing the temperature control logic to transmit the first signal for each of the plurality of heat detection elements to the processor.
50. The die package of any of clauses 40-49 comprising a plurality of heat generating elements, wherein the processor is configured to transmit a signal to each of the plurality of heat generating elements, causing the plurality of heat generating elements to generate heat.
51. The die package of clause 50, wherein the processor is configured to determine the corresponding operating temperature for each of the plurality of heat detection elements a predetermined amount of time after transmitting the signal to each of the plurality of heat generating elements.
52. The die package of any of clauses 40-51 comprising safety logic, wherein the processor is configured to transmit the error signal to the safety logic, causing the safety logic to disable at least one function.

Although the methods described above are with reference to the illustrated flowcharts, many other ways of performing the acts associated with the methods may be used. For example, the order of some operations may be changed, and some embodiments may omit one or more of the operations described and/or include additional operations.

In addition, the methods and system described herein may be at least partially embodied in the form of computer-implemented processes and apparatus for practicing those processes. The disclosed methods may also be at least partially embodied in the form of tangible, non-transitory machine-readable storage media encoded with computer program code that, when executed, causes a machine to fabricate at least one integrated circuit that performs one or more of the operations described herein. For example, the methods may be embodied in hardware, in executable instructions executed by a processor (e.g., software), or a combination of the two. The media may include, for example, RAMs, ROMs, CD-ROMs, DVD-ROMs, BD-ROMs, hard disk drives, flash memories, or any other non-transitory machine-readable storage medium. When the computer program code is loaded into and executed by a computer, the computer becomes an apparatus for causing a machine to fabricate the integrated circuit. The methods may also be at least partially embodied in the form of a computer into which computer program code is loaded or executed, such that, the computer becomes a special purpose computer for causing a machine to fabricate the integrated circuit. For instance, when implemented on a general-purpose processor, computer program code segments can configure the processor to create specific logic circuits. The methods may alternatively be at least partially embodied in application specific integrated circuits or any other integrated circuits for performing the methods.

In addition, terms such as “circuit,” “circuitry,” “logic,” and the like can include, alone or in combination, analog circuitry, digital circuitry, hardwired circuitry, programmable circuitry, processing circuitry, hardware logic circuitry, state machine circuitry, and any other suitable type of physical hardware components. Further, the embodiments described herein may be employed within various types of devices such as networking devices, telecommunication devices, smartphone devices, gaming devices, enterprise devices, storage devices (e.g., cloud storage devices), automobile systems (e.g., collision avoidance systems, object detection systems, navigation systems, etc.), and computing devices (e.g., cloud computing devices), among other types of devices.

The subject matter has been described in terms of exemplary embodiments. Because they are only examples, the claimed inventions are not limited to these embodiments. Changes and modifications may be made without departing the spirit of the claimed subject matter. It is intended that the claims cover such changes and modifications.

We claim:

1. A die package comprising:
a plurality of heat detection elements; and
a processor communicatively coupled to the plurality of heat detection elements, the processor configured to:
determine a corresponding operating temperature for each of the plurality of heat detection elements;
generate thermal error data based on the operating temperature and a threshold temperature for each of the plurality of heat detection elements; and
transmit an error signal based on the thermal error data.

2. The die package of claim 1, wherein the processor is configured to:
receive a first signal for each of the plurality of heat detection elements; and
based on the first signal for each of the plurality of heat detection elements, determine the corresponding operating temperature for each of the plurality of heat detection elements.

3. The die package of claim 2, wherein the processor is configured to:
execute a workload for a predetermined amount of time; and
receive the first signal for each of the plurality of heat detection elements when the workload has been executed.

4. The die package of claim 1 comprising a first thermal interface material, wherein a first of the plurality of heat detection elements contacts the first thermal interface material.

5. The die package of claim 4 comprising a lid, wherein the first thermal interface material is in contact with the lid.

6. The die package of claim 5 comprising a heatsink, wherein a second thermal interface material is between the lid and the heatsink, and wherein a second of the plurality of heat detection elements contacts the second thermal interface material.

7. The die package of claim 1 comprising a substrate, wherein a first of the plurality of heat detection elements contacts the substrate.

8. The die package of claim 1 comprising a memory device, wherein the processor is configured to read from the memory device the threshold temperature corresponding to each of the plurality of heat detection elements.

9. The die package of claim 8, wherein a first of the plurality of heat detection elements is positioned adjacent the processor, and a second of the plurality of heat detection elements is positioned adjacent the memory device.

10. The die package of claim 2 comprising temperature control logic electrically coupled to the plurality of heat detection elements, wherein the processor is communicatively coupled to the temperature control logic, and wherein the processor is configured to transmit a second signal to the temperature control logic, causing the temperature control logic to transmit the first signal for each of the plurality of heat detection elements to the processor.

11. The die package of claim 1 comprising a plurality of heat generating elements, wherein the processor is configured to transmit a signal to each of the plurality of heat generating elements, causing the plurality of heat generating elements to generate heat.

12. The die package of claim 11, wherein the processor is configured to determine the corresponding operating temperature for each of the plurality of heat detection elements a predetermined amount of time after transmitting the signal to each of the plurality of heat generating elements.

13. The die package of claim 1 comprising safety logic, wherein the processor is configured to transmit the error signal to the safety logic, causing the safety logic to disable at least one function.

14. A method by a processor comprising:
determining a corresponding operating temperature for each of a plurality of heat detection elements;
generating thermal error data based on the operating temperature and a threshold temperature for each of the plurality of heat detection elements; and
transmitting an error signal based on the thermal error data.

15. The method of claim 14, further comprising:
receiving a first signal for each of the plurality of heat detection elements; and
based on the first signal for each of the plurality of heat detection elements, determining the corresponding operating temperature for each of the plurality of heat detection elements.

16. The method of claim 15, further comprising:
executing a workload for a predetermined amount of time; and
receiving the first signal for each of the plurality of heat detection elements when the workload has been executed.

17. The method of claim 15, further comprising transmitting a second signal to temperature control logic, causing the temperature control logic to transmit the first signal for each of the plurality of heat detection elements to the processor.

18. The method of claim 14, further comprising transmitting a signal to each of a plurality of heat generating elements, causing the plurality of heat generating elements to generate heat.

19. A non-transitory, machine-readable storage medium comprises instructions that, when executed by at least one processor, cause the at least one processor to:
determine a corresponding operating temperature for each of the plurality of heat detection elements;
generate thermal error data based on the operating temperature and a threshold temperature for each of the plurality of heat detection elements; and
transmit an error signal based on the thermal error data.

20. A die package, comprising:
a plurality of heat detection elements;
thermal logic electrically coupled to the plurality of heat detection elements, the thermal logic configured to:
receive a first signal for each of the plurality of heat detection elements; and
based on the first signal for each of the plurality of heat detection elements, determine a corresponding operating temperature for each of the plurality of heat detection elements; and
a processor communicatively coupled to the thermal logic, the processor configured to:
receive the operating temperature for each of the plurality of heat detection elements from the thermal logic;
generate thermal error data based on the operating temperature and a threshold temperature for each of the plurality of heat detection elements; and
transmit an error signal based on the thermal error data.
